(19) United States
(12) Patent Application Publication
(10) Pub. No.: US 2026/0214833 A1
(43) Pub. Date: Jul. 23, 2026

(54) TRAY

(71) Applicant: Samsung Display Co., LTD., Yongin-si (KR)

(72) Inventors: Chang Hyeon KIM, Yongin-si (KR); Seong Jin PARK, Yongin-si (KR); Jong Heon LIM, Yongin-si (KR)

(21) Appl. No.: 19/299,965

(22) Filed: Aug. 14, 2025

(30) Foreign Application Priority Data
Jan. 17, 2025 (KR) 10-2025-0007413

(51) Int. Cl. H05K 7/20

(52) U.S. Cl. CPC H05K 7/20127; H05K 7/20954

(57) ABSTRACT

A tray includes a first pocket portion in which an internal space accommodating a display panel is defined, a second pocket portion spaced apart from the first pocket portion in a first direction, a first air passage disposed at one side of the first pocket portion, a second air passage disposed between the first pocket portion and the second pocket portion, and a third air passage disposed at one side of the second pocket portion. The first air passage and the second air passage are arranged in a direction inclined with respect to the first direction.

This application claims priority to Korean Patent Application Number 10-2025-0007413, filed on Jan. 17, 2025, and all the benefits accruing therefrom under 35 U.S.C. § 119, the content of which in its entirety is herein incorporated by reference.

### BACKGROUND

### 1. Field

Embodiments of the disclosure generally relate to a tray.

### 2. Description of Related Art

With the development of information technology, the importance of a display device, which is a connection medium between a user and information, is being highlighted. Accordingly, the use of display devices such as liquid crystal display devices and organic light-emitting display devices is increasing.

A typical display device is produced through several manufacturing processes, and components of the display device may be moved from a manufacturing line to an assembly line through a tray or may be transferred from an external company. For example, various types of substrate modules such as panels used in display devices may be loaded on trays and moved. When display panels are loaded on the trays and moved, edges of the display panels may be pressed.

### SUMMARY

A feature of the disclosure provides a tray capable of reducing a risk of damage to a display panel due to an edge of the display panel being pressed.

A feature of the disclosure provides a tray capable of reducing a risk that the tray is bent (e.g., tray curl).

A feature of the disclosure provides a tray capable of reducing a risk of fire occurrence.

In an embodiment of the disclosure, a tray may include a first pocket portion in which an internal space accommodating a display panel is defined, a second pocket portion spaced apart from the first pocket portion in a first direction, a first air passage disposed at one side of the first pocket portion, a second air passage disposed between the first pocket portion and the second pocket portion, and a third air passage disposed at one side of the second pocket portion, where the first air passage and the second air passage are arranged in a first inclined direction inclined with respect to the first direction.

In an embodiment, the first air passage, the second air passage, and the third air passage may be arranged in a zigzag pattern.

In an embodiment, the third air passage and the second air passage may be arranged in a second inclined direction inclined with respect to the first direction.

In an embodiment, the tray may further include a third pocket portion spaced apart from the second pocket portion in the first direction, a fourth pocket portion spaced apart from the third pocket portion in the first direction, a fourth air passage disposed between the third pocket portion and the fourth pocket portion, and a fifth air passage disposed at one side of the fourth pocket portion.

In an embodiment, based on a virtual line parallel to the first direction, the first air passage, the third air passage, and the fifth air passage may be arranged at one side with respect to the virtual line, and the second air passage and the fourth air passage may be arranged at an other side with respect to the virtual line.

In an embodiment, the tray may further include a fifth pocket portion spaced apart from the first pocket portion in a second direction, a sixth pocket portion spaced apart from the fifth pocket portion in the first direction, a first stopper disposed at an upper region of the tray in a plan view, a second stopper disposed in a central region of the tray in the plan view, and a third stopper disposed in a lower region of the tray in the plan view.

In an embodiment, the first stopper may include first stoppers, the second stopper may include second stoppers, and the third stopper may include third stoppers.

In an embodiment, each of the first stopper, the second stopper, and the third stopper may protrude further than a lower surface of the tray.

In an embodiment, the internal space may include a central area disposed at a center of the internal space, side areas extending from an edge of the central area, and corner areas extended to the side areas, where the first pocket portion includes: a main body portion including an outer wall surrounding at least a part of the side areas, and a guide portion surrounding the corner areas, and where the guide portion is extended to the outer wall.

In an embodiment, the main body portion may further include a circuit board receiving portion, and the side areas may include a first side area extending from a left side of the central area, a second side area extending from an upper side of the central area, a third side area extending from a right side of the central area, and a fourth side area extending from a lower side of the central area, the outer wall may include: a first outer wall surrounding at least a part of the first side area, a second outer wall surrounding at least a part of the second side area, a third outer wall surrounding at least a part of the third side area, and a fourth outer wall surrounding the circuit board receiving portion, and the guide portion may include: a first guide portion extended to the first outer wall and the second outer wall, a second guide portion extended to the second outer wall and the third outer wall, a third guide portion extended to the third outer wall and the fourth outer wall, and a fourth guide portion extended to the first outer wall and the fourth outer wall.

In an embodiment, each of the first guide portion, the second guide portion, the third guide portion, and the fourth guide portion may have a curved shape in a plan view.

In an embodiment, the corner areas may include a first corner area disposed at an upper left of the internal space, a second corner area disposed at an upper right of the internal space, a third corner area disposed at a lower right of the internal space, and a fourth corner area disposed at a lower left of the internal space, and the first corner area may be connected to the first guide portion, and the second corner area may be connected to the second guide portion, the third corner area may be connected to the third guide portion, and the fourth corner area may be connected to the fourth guide portion.

In an embodiment of the disclosure, a tray may include a first pocket portion in which an internal space accommodating a display panel is defined, where the internal space includes: a central area disposed at a center of the internal space, side areas extending from edges of the central area, and corner areas connecting the side areas, and where the first pocket portion includes: a main body portion including an outer wall surrounding at least a part of the side areas, and a guide portion surrounding the corner areas, and where the guide portion is extended to the outer wall.

In an embodiment, the tray may further include a second pocket portion spaced apart from the first pocket portion in a first direction, a first air passage disposed at one side of the first pocket portion, a second air passage disposed between the first pocket portion and the second pocket portion, and a third air passage disposed at one side of the second pocket portion, in which the first air passage and the second air passage are arranged in a direction inclined with respect to the first direction.

In an embodiment, based on a virtual line parallel to the first direction, the first air passage and the third air passage may be arranged on one side with respect to the virtual line, and the second air passage may be arranged at an other side with respect to the virtual line.

In an embodiment, the third air passage and the second air passage may be arranged in a first inclined direction inclined with respect to the first direction.

In an embodiment, the tray may further include a fifth pocket portion spaced apart from the first pocket portion in a second direction, a sixth pocket portion spaced apart from the fifth pocket portion in the first direction, a first stopper disposed in an upper region of the tray in a plan view, a second stopper disposed in a central region of the tray in the plan view, and a third stopper disposed in a lower region of the tray in the plan view.

In an embodiment, the first stopper may include first stoppers, the second stopper may include second stoppers, the third stopper may include third stoppers, and each of the first stopper, the second stopper, and the third stopper may protrude further than a lower surface of the tray.

In an embodiment, the main body portion may further include a circuit board receiving portion, the side areas may include: a first side area extending from a left side of the central area, a second side area extending from an upper side of the central area, a third side area extending from a right side of the central area, and a fourth side area extending from a lower side of the central area, the outer wall may include: a first outer wall surrounding at least a part of the first side area, a second outer wall surrounding at least a part of the second side area, a third outer wall surrounding at least a part of the third side area, and a fourth outer wall surrounding the circuit board receiving portion, and the guide portion may include: a first guide portion extended to the first outer wall and the second outer wall, a second guide portion extended to the second outer wall and the third outer wall, a third guide portion extended to the third outer wall and the fourth outer wall, and a fourth guide portion extended to the first outer wall and the fourth outer wall, and each of the first guide portion, the second guide portion, the third guide portion, and the fourth guide portion may have a curved shape in a plan view.

In an embodiment, the corner areas may include: a first corner area disposed at an upper left of the internal space, a second corner area disposed at an upper right of the internal space, a third corner area disposed at a lower right of the internal space, and a fourth corner area disposed at a lower left of the internal space, and the first corner area may be extended to the first guide portion, the second corner area may be connected to the second guide portion, the third corner area may be connected to the third guide portion, and the fourth corner area may be connected to the fourth guide portion.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a schematic plan view of an embodiment of a tray.

FIG. 2 is a schematic plan view of an embodiment of a pocket portion.

FIG. 3 is a schematic plan view of an embodiment of an internal space.

FIG. 4 is a schematic plan view of a pocket portion according to Comparative Example 1.

FIG. 5 is a schematic plan view of a pocket portion according to Comparative Example 2.

FIG. 6 is a schematic plan view of a pocket portion according to Comparative Example 3.

FIG. 7 is a schematic plan view of a tray according to Comparative Example 4.

FIG. 8 is a schematic plan view of an embodiment of a display device.

FIG. 9 is a block diagram of an embodiment of an electronic device.

FIG. 10 shows schematic views of various embodiments of an electronic device.

### DETAILED DESCRIPTION

As the disclosure allows for various changes and numerous embodiments, particular embodiments will be illustrated in the drawings and described in detail in the written description. However, this is not necessarily intended to limit the disclosure to particular modes of practice, and it is to be appreciated that all changes, equivalents, and substitutes that do not depart from the spirit and technical scope of the disclosure are encompassed in the disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element. In the disclosure, the singular forms are intended to include the plural forms as well, unless the context clearly indicates otherwise.

It will be further understood that the terms “comprise”, “include”, “have”, etc. when used in the disclosure, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed “on” a second part, the first part may be not only “directly on” the second part but a third part may intervene between them. In addition, when it is expressed that a first part such as a layer, a film, a region, or a plate is formed on a second part, the surface of the second part on which the first part is formed is not necessarily limited to an upper surface of the second part but may include other surfaces such as a side surface or a lower surface of the second part. To the contrary, in case that a first part such as a layer, a film, a region, or a plate is “under” a second part, the first part may be not only “directly under” the second part but a third part may intervene between them.

The disclosure relates to a tray. Hereinafter, embodiments of the disclosure will be described in detail with reference to the accompanying drawings.

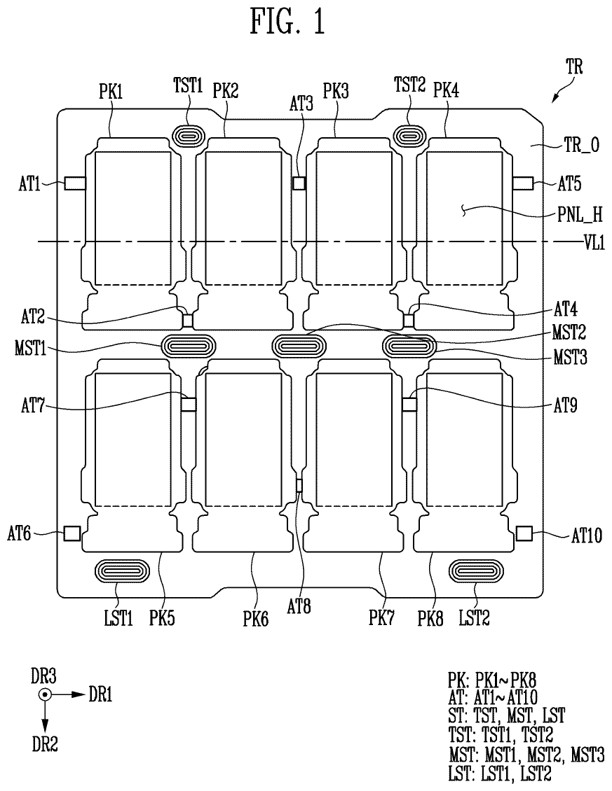

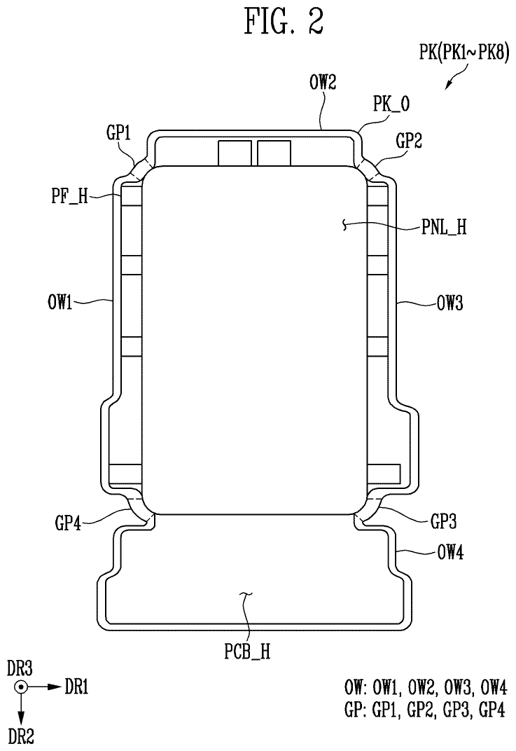

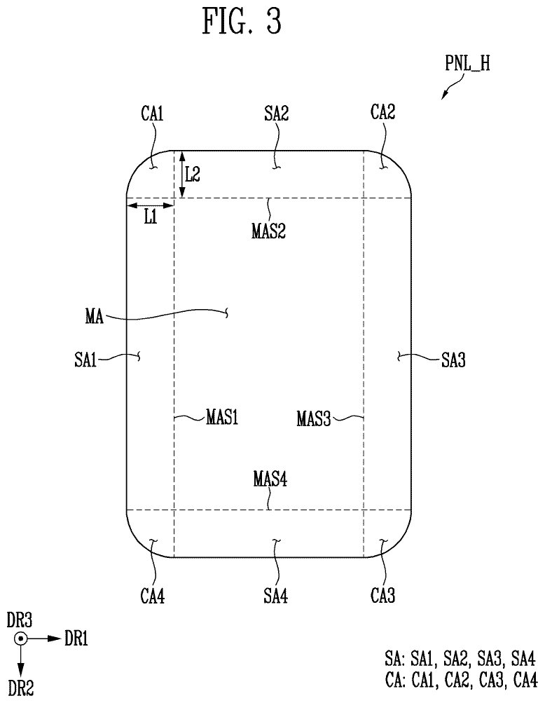

FIG. 1 is a schematic plan view of an embodiment of a tray TR. FIG. 2 is a schematic plan view of an embodiment of a pocket portion PK. FIG. 3 is a schematic plan view of an embodiment of an internal space PNL_H.

Referring to FIG. 1, the tray TR may include the pocket portion PK in which the internal space PNL_H for accommodating components to be included in an electronic device is defined, and an edge portion TR_O surrounding the pocket portion PK. The edge portion TR_O may surround the pocket portion PK and may form an outer shape of the tray TR. In an embodiment, the shape of the edge portion TR_O may correspond to that of the tray TR, for example.

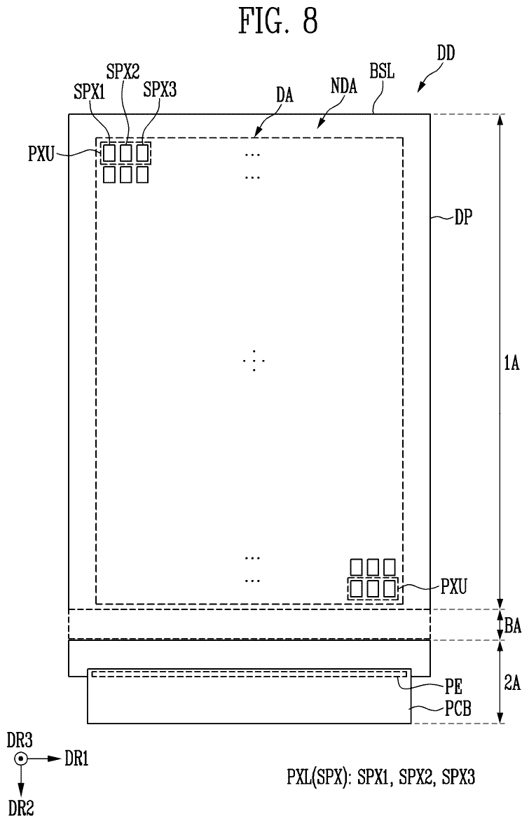

The components to be included in the electronic device are components to be included in a display device, and may include a semi-finished product from which a module process corresponding to an assembly process is omitted, such as a display panel DP (refer to FIG. 8), an open cell, a printed circuit board (“PCB”), or the like. In an embodiment, the internal space PNL_H of the tray TR may accommodate the display panel DP, for example.

The pocket portion PK may include a plurality of pocket portions. In an embodiment, the tray TR may have two or more pocket portions PK. As shown in FIG. 1, the tray TR includes eight pocket portions PK, for example. However, the disclosure is not limited thereto, and in an embodiment, the tray TR may include at least two or more pocket portions PK next (adjacent) to each other in a horizontal direction. The embodiment shown in FIG. 1 is described below for convenience.

The pocket portion PK may include a first pocket portion PK1, a second pocket portion PK2, a third pocket portion PK3, a fourth pocket portion PK4, a fifth pocket portion PK5, a sixth pocket portion PK6, a seventh pocket portion PK7, and an eighth pocket portion PK8. The first pocket portion PK1, the second pocket portion PK2, the third pocket portion PK3, and the fourth pocket portion PK4 may be spaced apart and sequentially arranged in a first direction DR1. In an embodiment, the second pocket portion PK2 may be spaced apart from the first pocket portion PK1 in the first direction DR1, the third pocket portion PK3 may be spaced apart from the second pocket portion PK2 in the first direction DR1, and the fourth pocket portion PK4 may be spaced apart from the third pocket portion PK3 in the first direction DR1, for example. The fifth pocket portion PK5, the sixth pocket portion PK6, the seventh pocket portion PK7, and the eighth pocket portion PK8 may be spaced apart and sequentially arranged in the first direction DR1. In an embodiment, the sixth pocket portion PK6 may be spaced apart from the fifth pocket portion PK5 in the first direction DR1, the seventh pocket portion PK7 may be spaced apart from the sixth pocket portion PK6 in the first direction DR1, and the eighth pocket portion PK8 may be spaced apart from the seventh pocket portion PK7 in the first direction DR1, for example.

The first pocket portion PK1, the second pocket portion PK2, the third pocket portion PK3, and the fourth pocket portion PK4 may be arranged closer to an upper side of the tray TR in a plan view than the fifth pocket portion PK5, the sixth pocket portion PK6, the seventh pocket portion PK7, and the eighth pocket portion PK8. In an embodiment, the first pocket portion PK1, the second pocket portion PK2, the third pocket portion PK3, and the fourth pocket portion PK4 may be arranged at the upper side of the tray TR in a plan view, and the fifth pocket portion PK5, the sixth pocket portion PK6, the seventh pocket portion PK7, and the eighth pocket portion PK8 may be arranged at a lower side of the tray TR in the plan view, for example.

The fifth pocket portion PK5 may be spaced apart from the first pocket portion PK1 in a second direction DR2, the sixth pocket portion PK6 may be spaced apart from the second pocket portion PK2 in the second direction DR2, the seventh pocket portion PK7 may be spaced apart from the third pocket portion PK3 in the second direction DR2, and the eighth pocket portion PK8 may be spaced apart from the fourth pocket portion PK4 in the second direction DR2.

Hereinafter, in the disclosure, the first direction DR1 and the second direction DR2 correspond to a horizontal direction and a vertical direction, respectively, when the tray TR is viewed in a plan view, and a third direction DR3 is defined as a direction perpendicular to the plane.

Referring to FIG. 2, the pocket portion PK may include a main body portion PK_O and a guide portion GP. The pocket portion PK as shown in FIG. 2 may correspond to each of the first to eighth pocket portions PK1 to PK8 of FIG. 1. The main body portion PK_O of the pocket portion PK may include the internal space PNL_H and a circuit board receiving portion PCB_H.

The main body portion PK_O of the pocket portion PK may include a base portion corresponding to a bottom surface (e.g., a lower surface) and an outer wall OW extended to or connected to the base portion to form an outer periphery of the main body portion PK_O. The outer wall OW may extend in the third direction DR3 from the edge of the bottom surface. At least a part of the base portion of the main body portion PK_O may define the internal space PNL_H and a circuit board receiving portion PCB_H.

The internal space PNL_H and the circuit board receiving portion PCB_H may be extended to each other. The internal space PNL_H may accommodate the display panel DP, and the circuit board receiving portion PCB_H may accommodate a circuit board (e.g., the PCB of FIG. 8) connected to the display panel.

Referring to FIG. 3, the internal space PNL_H may include a central area MA, side areas SA, and corner areas CA. The internal space PNL_H may have a shape corresponding to the display panel DP. A planar area of the internal space PNL_H may be greater than or equal to a planar area of the display panel DP.

The central area MA corresponds to the center of the internal space PNL_H, and may be disposed in the center of the internal space PNL_H. In an embodiment, the central area MA may have a quadrangular shape, e.g., rectangular shape, and the central area MA includes a first edge MAS1 corresponding to a left side of the central area MA, a second edge MAS2 of an upper side of the center region MA, a third edge MAS3 of a right side of the central area MA, and a fourth edge MAS4 of a lower side of the central area MA. However, the disclosure is not limited thereto, and in embodiments, the central area MA may have various shapes.

The side areas SA may include a first side area SA1 extending from the first edge MAS1, a second side area SA2 extending from the second edge MAS2, a third side area SA3 extending from the third edge MAS3, and a fourth side area SA4 extending from the fourth edge MAS4.

The first side area SA1 may be extended to the first edge MAS1, the second side area SA2 may be extended to the second edge MAS2, the third side area SA3 may be extended to third edge MAS3, and the fourth side area SA4 may be extended to the fourth edge MAS4.

The corner areas CA may be disposed at corners of the internal space PNL_H. The corner areas CA may connect the side areas SA to each other.

The corner areas CA may include a first corner area CA1 connecting the first side area SA1 and the second side area SA2, a second corner area CA2 connecting the second side area SA2 and the third side area SA3, a third corner area CA3 connecting the third side area SA3 and the fourth side area SA4, and a fourth corner area CA4 connecting the fourth side area SA4 and the first side area SA1.

The first corner area CA1 may be disposed at the upper left of the internal space PNL_H. The second corner area CA2 may be disposed at the upper right of the internal space PNL_H. The third corner area CA3 may be disposed at the lower right of the internal space PNL_H. The fourth corner area CA4 may be disposed at the lower left of the internal space PNL_H.

In an embodiment, the corner areas CA may have a rounded corner shape, as shown in FIG. 3, but are not necessarily limited thereto. In an embodiment, the corner areas CA may have an angled corner shape, for example.

A length of a side where each of the corner areas CA and each of the side areas SA meet may be greater than 0 centimeter (cm) and less than or equal to 2 cm. In an embodiment, the length of a side L1 where the first side area SA1 and the first corner area CAL meet may be greater than 0 cm and less than or equal to 2 cm, for example. The length of a side L2 where the second side area SA2 and the first corner area CAL meet may be greater than 0 cm and less than or equal to 2 cm.

That is, according to the disclosure, each of the corner areas CA may be defined as an area disposed at the corner of the internal space PNL_H without a straight-line distance from the edge of the internal space PNL_H exceeding 2 cm.

Referring to FIGS. 1 and 2 in combination with FIG. 3, the outer wall OW may surround at least a part of each of the side areas SA. In an embodiment, the outer wall OW may surround at least a part of the edge of each of the side areas SA, for example. The outer wall OW may include a first outer wall OW1, a second outer wall OW2, a third outer wall OW3, and a fourth outer wall OW4.

The first outer wall OW1 may be disposed on the left side of the internal space PNL_H and surround at least a part of the first side area SA1. In an embodiment, the first outer wall OW1 may surround at least a part of an edge of the first side area SA1, for example. The second outer wall OW2 may be disposed on the upper side of the internal space PNL_H and surround at least a part of the second side area SA2. In an embodiment, the second outer wall OW2 may surround at least a part of an edge of the second side area SA2, for example. The third outer wall OW3 may be disposed on the right side of the internal space PNL_H and may surround at least a part of the third side area SA3. In an embodiment, the third outer wall OW3 may surround at least a part of the edge of the third side area SA3, for example. The fourth outer wall OW4 may be disposed on the lower side of the internal space PNL_H and surround the circuit board receiving portion PCB_H. The fourth outer wall OW4 may be extended to the circuit board receiving portion PCB_H.

The first outer wall OW1, the second outer wall OW2, the third outer wall OW3, and the fourth outer wall OW4 may not surround the corner area CA. In an embodiment, the first outer wall OW1, the second outer wall OW2, the third outer wall OW3, and the fourth outer wall OW4 may not be connected to the corner area CA, for example. In an embodiment, the first outer wall OW1, the second outer wall OW2, the third outer wall OW3, and the fourth outer wall OW4 may expose the corner area CA, for example.

The guide portion GP may surround the exposed corner area CA. The guide portion GP may be extended to at least a part of the outer wall OW to surround at least a part of the edge of the internal space PNL_H.

When a component (e.g., the display panel DP) to be included in the electronic device is disposed in the internal space PNL_H, the guide portion GP may contact the component to be included, and may fix (or support) the component to be included in the electronic device.

The guide portion GP may include a first guide portion GP1, a second guide portion GP2, a third guide portion GP3, and a fourth guide portion GP4. The guide portion GP may be connected to the corner area CA and may not be connected to the side area SA.

The first guide portion GP1 may be extended to the first outer wall OW1 and the second outer wall OW2, and may be disposed next (adjacent) to the first corner area CA1. In an embodiment, the first guide portion GP1 may be connected to the first corner area CA1, for example. In an embodiment, the first guide portion GP1 may surround a part of the first corner area CA1, for example.

The second guide portion GP2 may be extended to the second outer wall OW2 and the third outer wall OW3, and may be disposed next (adjacent) to the second corner area CA2. In an embodiment, the second guide portion GP2 may be connected to the second corner area CA2, for example. In an embodiment, the second guide portion GP2 may surround a part of the second corner area CA2, for example.

The third guide portion GP3 may be extended to the third outer wall OW3 and the fourth outer wall OW4, and may be disposed next (adjacent) to the third corner area CA3. In an embodiment, the third guide portion GP3 may be connected to the third corner area CA3, for example. In an embodiment, the third guide portion GP3 may surround a part of the third corner area CA3, for example.

The fourth guide portion GP4 may be extended to the fourth outer wall OW4 and the first outer wall OW1, and may be disposed next (adjacent) to the fourth corner area CA4. In an embodiment, the fourth guide portion GP4 may be connected to the fourth corner area CA4, for example. In an embodiment, the fourth guide portion GP4 may surround a part of the fourth corner area CA4, for example.

The first to fourth guide portions GP1 to GP4 may have shapes corresponding to the first to fourth corner areas CA1 to CA4, respectively. In an embodiment, when each of the first to fourth corner areas CA1 to CA4 has a shape with a rounded corner, each of the first to fourth guide portions GP1 to GP4 may a shape with a rounded corner, for example. Each of the first to fourth guide portions GP1 to GP4 may have a curved shape in a plan view.

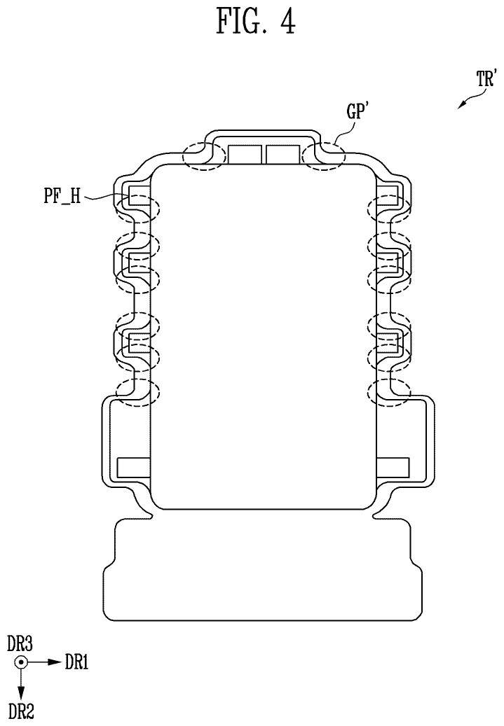

The guide portion GP may not be connected to the side area SA of the internal space PNL_H (e.g., may not contact the side area SA) and may be connected to the corner area CA, and the tray TR according to the disclosure may reduce a risk that an edge of the display panel DP is pressed when the display panel DP is disposed in the internal space PNL_H, which will be described below with reference to the drawings following FIG. 4.

In an embodiment, the tray TR may further include a handle receiving portion PF_H. The handle receiving portion PF_H may be a space for receiving (or accommodating) a handle of a protective film which protects a component (e.g., the display panel DP) to be included in the electronic device. In an embodiment, the handle receiving portion PF_H may include a plurality of handle receiving portions.

In an embodiment, the handle receiving portion PF_H may be formed so that at least a part of the base portion may protrude in the third direction DR3. The handle of the protective film may serve as a handle of the protective film when the protective film is removed, and the handle of the protection film may be disposed on the handle receiving portion PF_H. In an embodiment, the space for receiving (or accommodating) the handle of the protective film may be formed at various locations. In an embodiment, the handle receiving portion PF_H may be omitted when protective film is not attached to the component to be included in the electronic device.

The tray TR may further include an air passage AT. The air passage AT may be a passage through which air flows when the trays TR are stacked in multiple layers. The air passage AT may be a passage through which bubbles formed during the processes of forming the display device move. An area in which the air passage AT is formed and surroundings thereof may form a step, and air may flow between spaces in which the step is formed. Air may flow in the air passage AT, and the external pressure generated during the transport of the tray TR may be distributed so that excessive pressure may be not applied to the configuration transported by the tray TR.

The air passage AT may include a first air passage AT1, a second air passage AT2, a third air passage AT3, a fourth air passage AT4, a fifth air passage AT5, a sixth air passage AT6, a seventh air passage AT7, an eighth air passage AT8, a ninth air passage AT9, and a tenth air passage AT10.

The first air passage AT1 may be arranged on one side (e.g., the left side) of the first pocket portion PK1. The second air passage AT2 may be arranged on an opposite side (e.g., the right side) of the first pocket portion PK1 or on one side of the second pocket portion PK2. The second air passage AT2 may be arranged between the first pocket portion PK1 and the second pocket portion PK2. The third air passage AT3 may be disposed on an opposite side of the second pocket portion PK2 or on one side of the third pocket portion PK3. The third air passage AT3 may be disposed between the second pocket portion PK2 and the third pocket portion PK3. The fourth air passage AT4 may be disposed on an opposite side of the third pocket portion PK3 or on one side of the fourth pocket portion PK4. The fourth air passage AT4 may be disposed between the third pocket portion PK3 and the fourth pocket portion PK4. The fifth air passage AT5 may be disposed on an opposite side of the fourth pocket portion PK4.

The second air passage AT2 and each of the first air passage AT1 and the third air passage AT3 may be arranged in a direction inclined with respect to the first direction DR1. In an embodiment, the first air passage AT1 and the second air passage AT2 may be arranged in a first inclined direction diagonally across between the first direction DR1 and the second direction DR2, for example. In an embodiment, the third air passage AT3 and the second air passage AT2 may be arranged in a second inclined direction crossing between first direction DR1 and a direction opposite to the second direction DR2, for example. The fourth air passage AT4 and each of the third air passage AT3 and the fifth air passage AT5 may be arranged in a direction inclined with respect to the first direction DR1. In an embodiment, the third air passage AT3 and the fourth air passage AT4 may be arranged diagonally across between the first direction DR1 and the second direction DR2, for example. In an embodiment, the fourth air passage AT4 and the fifth air passage AT5 may be arranged in a diagonal direction crossing between the first direction DR1 and a direction opposite to the second direction DR2, for example.

The first air passage AT1, the second air passage AT2, the third air passage AT3, the fourth air passage AT4, and the fifth air passage AT5 may be arranged in a zigzag pattern. In an embodiment, based on a virtual line VL1 parallel to the first direction DR1, the first air passage AT1, the third air passage AT3, and the fifth air passage AT5 may be arranged on one side (e.g., the right side or the upper side) with respect to the virtual line VL1, and the second air passage AT2 and the fourth air passage AT4 may be arranged on an opposite side (e.g., the left side or the lower side) with respect to the virtual line VL1, for example. However, the disclosure is not limited thereto, and in an embodiment, the first air passage AT1, the third air passage AT3, and the fifth air passage AT5 may be arranged on the left side with respect to the virtual line VL1, and the second air passage AT2 and the fourth air passage AT4 may be arranged on the right side with respect to the virtual line VL1.

In an embodiment, arranged in a zigzag pattern” may mean “alternately arranged on one side and an opposite side with respect to the virtual line VL1 parallel to the first direction DR1”, for example.

The sixth air passage AT6 may be disposed on one side (e.g., the left side) of the fifth pocket portion PK5. The seventh air passage AT7 may be disposed on an opposite side (e.g., the right side) of the fifth pocket portion PK5 or on one side of the sixth pocket portion PK6. The seventh air passage AT7 may be arranged between the fifth pocket portion PK5 and the sixth pocket portion PK6. The eighth air passage AT8 may be arranged on an opposite side of the sixth pocket portion PK6 or on one side of the seventh pocket portion PK7. The eighth air passage AT8 may be disposed between the sixth pocket portion PK6 and the seventh pocket portion PK7. The ninth air passage AT9 may be disposed on an opposite side of the seventh pocket portion PK7 or on one side of the eighth pocket PK8. The ninth air passage AT9 may be disposed between the seventh pocket portion PK7 and the eighth pocket portion PK8. The tenth air passage AT10 may be disposed on an opposite side of the eighth pocket portion PK8.

The seventh air passage AT7 and each of the sixth air passage AT6 and the eighth air passage AT8 may be arranged in a direction inclined with respect to the first direction DR1. In an embodiment, the sixth air passage AT6 and the seventh air passage AT7 may be arranged in a diagonal direction across between the first direction DR1 and a direction opposite to the second direction DR2, for example. In an embodiment, the seventh air passage AT7 and the eighth air passage AT8 may be disposed diagonally across between the first direction DR1 and the second direction DR2, for example.

The ninth air passage AT9 and each of the eighth air passage AT8 and the tenth air passage AT10 may be arranged in a direction inclined with respect to the first direction DR1. In an embodiment, the eighth air passage AT8 and the ninth air passage AT9 may be arranged in a diagonal direction across between the first direction DR1 and a direction opposite to the second direction DR2, for example. In an embodiment, the ninth air passage AT9 and the tenth air passage AT10 may be arranged diagonally across between the first direction DR1 and the second direction DR2, for example.

The sixth air passage AT6, the seventh air passage AT7, the eighth air passage AT8, the ninth air passage AT9, and the tenth air passage AT10 may be arranged in a zigzag pattern. In an embodiment, based on a virtual line parallel to the first direction DR1, the sixth air passage AT6, the eighth air passage AT8, and the tenth air passage AT10 may be arranged on one side (e.g., the left side or the lower side) with respect to the virtual line, and the seventh air passage AT7 and the ninth air passage AT9 may be arranged on an opposite side (e.g., the right side or the upper side) with respect to the virtual line, for example. However, the disclosure is not limited thereto, and in an embodiment, the sixth air passage AT6, the eighth air passage AT8, and the tenth air passage AT10 may be arranged on the right side with respect to the virtual line, and the seventh air passage AT7 and the ninth air passage AT9 may be arranged on the left side with respect to the virtual line.

The air passage AT is arranged in a zigzag pattern, so that the tray TR according to the disclosure may reduce the risk that the tray TR may curl when the trays TR are stacked in multiple layers.

The tray TR may further include a stopper ST. The stopper ST may control the movements of the tray TR when the tray TR is moved. In an embodiment, the stopper ST may cause the tray TR to move, or may stop moving the tray TR, for example.

The stopper ST may include a first stopper TST, a second stopper MST, and a third stopper LST. The first stopper TST may be disposed in an upper region of the tray TR in a plan view. The second stopper MST may be disposed in a central region of the tray TR in a plan view. The third stopper LST may be disposed in a lower region of the tray TR in a plan view. In an embodiment, the first stopper TST may be disposed above the first to fourth pocket portions PK1 to PK4 in the plan view, the second stopper MST may be disposed between a region where the first to fourth pocket portions PK1 to PK4 are arranged and a region where the fifth to eighth pocket portions PK5 to PK8 are arranged in the plan view, and the third stopper LST may be disposed below a region where the fifth to eighth pocket portions PK5 to PK8 are arranged in the plan view, for example.

The first stopper TST may include a plurality of first stoppers TST. The second stopper MST may include a plurality of second stoppers MST. The third stopper LST may include a plurality of third stoppers LST. In an embodiment, the first stoppers TST may include a (1-1)th stopper TST1 disposed between an upper side of the first pocket portion PK1 and an upper side of the second pocket portion PK2, and a (1-2)th stopper TST2 disposed between an upper side of the third pocket portion PK3 and an upper side of the fourth pocket portion PK4, for example. In an embodiment, the second stoppers MST may include a (2-1)th stopper MST1, a (2-2)th stopper MST2, and a (2-3)th stopper MST3 disposed between the upper sides of the fifth to eighth pocket portions PK5 to PK8, respectively, for example. In an embodiment, the third stoppers LST may include a (3-1)th stopper LST1 disposed under the fifth pocket portion PK5 (or disposed on the lower side of the fifth pocket portion PK5) and a (3-2)th stopper LST2 disposed under the eighth pocket portion PK8 (or disposed on the lower side of the eighth pocket portion PK8), for example. However, the disclosure is not limited thereto. The position of each of the first stoppers TST, the second stoppers MST, and the third stoppers LST may be changed.

In FIG. 1, an embodiment in which there are two first stoppers TST, three second stoppers MST, and two third stoppers LST is shown, but the disclosure is not limited thereto. The numbers of first stopper TST, the number of second stoppers MST, and the number of third stoppers LST may vary.

Each of the first stopper TST, the second stopper MST, and the third stopper LST may protrude further in a direction opposite to the third direction DR3 than a lower surface of the tray TR. Accordingly, when the tray TR is moved on a conveyor belt, each of the first stopper TST, the second stopper MST, and the third stopper LST may contact the conveyor belt and the movement of the tray TR may be controlled.

The stopper ST according to the disclosure is disposed in each of the upper, central, and lower regions of the tray TR, so that a contact area between the stopper ST and the conveyor belt may be increased. The stopper ST in contact with the conveyor belt may move the tray TR on the conveyor belt. The stopper ST according to the disclosure is disposed in each of the upper, central, and lower regions of the tray TR, so that even when one stopper ST is sandwiched between conveyor belts, the remaining stoppers ST may sufficiently in contact with the conveyor belt, so that the tray TR may be moved appropriately.

Hereinafter, based on the embodiment of FIG. 2 and the comparative examples of FIGS. 4 to 6, the degree of edge indentation of the display panel transferred by the trays of the embodiment and the comparative examples will be described. The embodiment and the comparative examples are merely for explaining the disclosure in more detail, and the disclosure is not limited by the embodiment and the comparative examples.

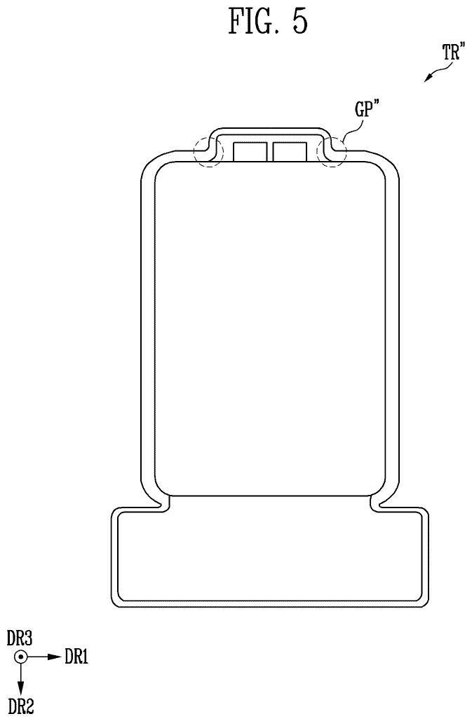

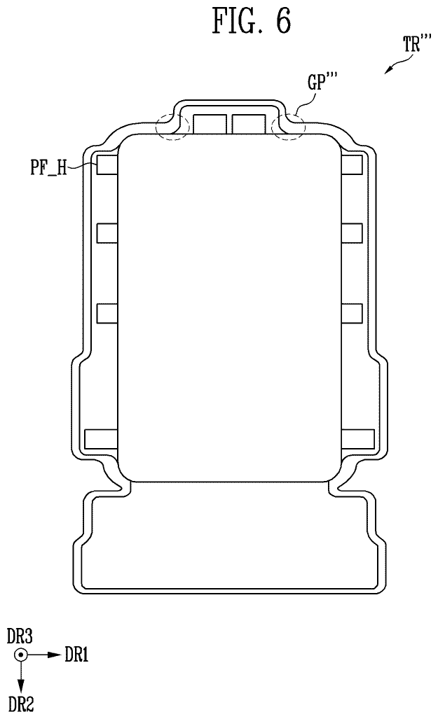

FIG. 4 is a schematic plan view of the pocket portion according to Comparative Example 1. FIG. 5 is a schematic plan view of the pocket portion according to Comparative Example 2. FIG. 6 is a schematic plan view of the pocket portion according to Comparative Example 3. At least a part of guide portions GP′, GP″, and GP′″ of the comparative examples of FIGS. 4 to 6 is connected to at least a part of the side area SA. In FIGS. 4 to 6, a region in which each of the guide portions GP′, GP″, and GP′″ connected to at least the part of the side area SA is disposed is shown in dashed lines.

Referring to FIG. 4, a tray TR′ of Comparative Example 1 may include the handle receiving portion PF_H disposed on the upper side, the left side, and the right side of the internal space PNL_H. When Comparative Example 1 is compared against the embodiment of FIG. 2, at least parts of the guide portions GP′ of Comparative Example 1 may be connected to the side areas SA. In an embodiment, at least some of the guide portions GP′ may be connected to the first, second, and third side areas SA1, SA2, and SA3, for example.

Referring to FIG. 5, when Comparative Example 2 is compared with the embodiment of FIG. 2, a tray TR″ of Comparative Example 2 may not include the handle receiving portion PF_H disposed on the left side and the right side of the internal space PNL_H. The guide portion GP″ of Comparative Example 2 may be connected to the second side area SA2.

Referring to FIG. 6, when Comparative Example 3 is compared with the embodiment of FIG. 2, the guide portion GP′″ of Comparative Example 3 may be connected to the second side area SA2.

In order to compare the degree of edge indentation of the display panel in the embodiment and the comparative examples, the display panel DP was disposed in the internal space PNL_H of each of the embodiment and Comparative Examples 1 to 3. After an autoclave process of bonding a window to the upper part of the display panel DP was performed, the tray was moved, and a process of irradiating ultraviolet rays was performed.

After the display panel DP was bent to form a finished display device, the upper edge indentation and the left and right edges indentation of the display panel DP were measured. For a relatively accurate measurement, the indentation on the upper edge and the left and right edges were measured after the adhesive between the display panel DP and the window was completely hardened. Table 1 below shows results of measuring the edge indentation of the display panel DP.

TABLE 1

| | Upper edge | Left and right edge |
|---|---|---|
| Classification | indentation | indentation |
| Comparative Example 1 | 5F/138ea | 12F/138ea |
| Comparative Example 2 | 13F/40ea | 2F/40ea |
| Comparative Example 3 | 10F/32ea | 0F/32ea |
| Embodiment | 0F/30ea | 0F/30ea |

In Table 1 above, “ea” means the number of test subjects which have been evaluated, and “F” means the number of test subjects in which edge indentation has occurred. In an embodiment, 13F/40ea means that edge indentation occurred in 13 out of 40 subjects, for example.

Referring to Table 1, edge indentation occurred less in the display panel DP conveyed by the tray TR in the embodiment than in the display panel DP conveyed by each of the trays TR′, TR″ and TR′″ according to Comparative Examples 1, 2, and 3.

When the number of guide portions is increased to support the display panel DP, the display panel DP may be stably supported. However, interference between the guide portion and the display panel DP is increased (e.g., the area or the number of times the display panel DP contacts the guide portion is increased), so that pressing (or indentation) of the display panel DP may be increased. When the number of guide portions is reduced in order to reduce interference between the guide portions and the display panel DP, the display panel DP is not properly supported, so that the display panel DP may be shaken during transportation. According to the tray TR according to the disclosure, the guide portion GP is disposed to be connected to the corner area CA, so that interference between the guide portion GP and the display panel DP may be reduced, and the display panel DP may be stably supported.

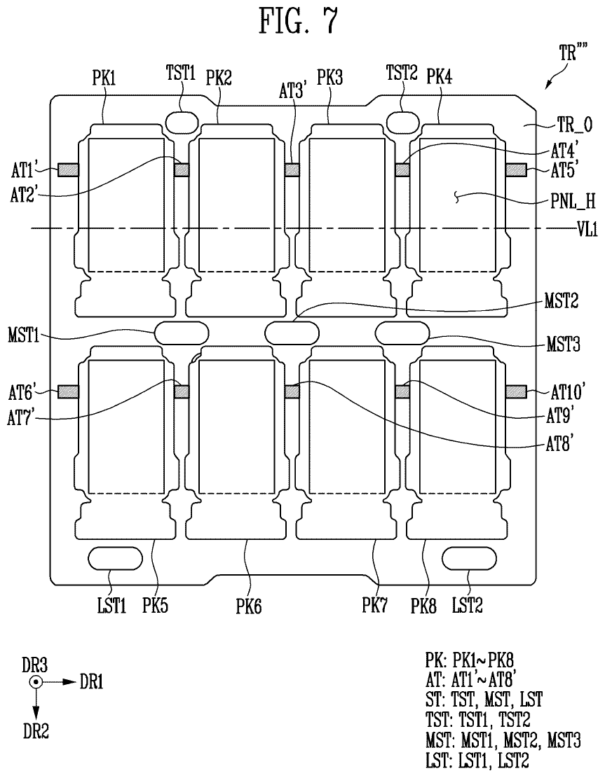

Hereinafter, based on the embodiment of FIG. 1 and the comparative example of FIG. 7, the probability of fire occurrence in the trays of the embodiment and the comparative example will be described. The embodiment and the comparative examples are merely for explaining the disclosure in more detail, and the disclosure is not limited by the embodiment and the comparative examples.

FIG. 7 is a schematic plan view of a tray according to Comparative Example 4.

Referring to FIG. 7, when Comparative Example 4 is compared with the embodiment of FIG. 1, first to fifth air passages AT1′ to AT5′ and sixth to tenth air passages AT6′ to AT10′ of Comparative Example 4 are arranged next to each other (or side by side, or horizontally) in the first direction DR1.

In order to compare the probability of fire occurrence in the embodiment and the comparative examples, the display panel DP was disposed in the internal space PNL_H of each of the embodiment and Comparative Example 4, and an autoclave process of bonding a window to the upper part of the display panel DP and a process of irradiating ultraviolet rays were performed after the autoclave process. The autoclave process and the ultraviolet irradiation process were carried out repeatedly. Table 2 below shows results of measuring the number of repeated processes and whether a fire has occurred.

TABLE 2

| Classification | Number of Processes |
|---|---|
| Comparative Example 4 | 13 times (2F/10ea) |
| Embodiment | 20 times (0F/10ea) |

In Table 2 above, “ea” refers to the number of test subjects which have been evaluated, and “F” refers to the numbers of test subjects in which a fire alarm has occurred. In an embodiment, 2F/10ea means that fire alarms have occurred in 2 out of 10 test subjects, for example. In addition, “the number of repeatedly performed processes is 13” means that “the autoclave process and the ultraviolet irradiation process were performed 13 times.” In the description, “the number of repeatedly performed processes is two” means “the autoclave process, the ultraviolet irradiation process, the autoclave process and the ultraviolet irradiation process have been performed,” for example

In a tray TR″″ of Comparative Example 4, no fire alarm was generated until the process of irradiating ultraviolet rays was repeated 12 times after the autoclave process, and after the process of irradiation with ultraviolet rays after the autoclave process was repeated 13 times, fire alarms were generated in 2 out of 10 test subjects. In the tray TR of the embodiment, even when the process of irradiating ultraviolet rays after the autoclave process is repeated 20 times, no fire alarms occurred.

As a result, it may be confirmed that less fires occur in the tray TR. In the tray TR in the embodiment, the air passage AT is disposed in a zigzag pattern, so that the tray TR may curl relatively less than the tray TR′″ of Comparative Example 4 when the temperature increases in the process of irradiating ultraviolet rays. In the process of irradiating ultraviolet rays, when the tray curls when the temperature increases, the tray may be caught (or sandwiched) between conveyor belts, resulting in a fire.

According to the tray TR according to the disclosure, the air passages AT may be arranged in a zigzag pattern. Thus, heat may be effectively discharged through the air passages AT, and bubbles between the display panel DP and the window may be discharged along the air passage AT. Therefore, the risk of the tray TR being curled may be reduced, and the risk of a fire occurring when the tray TR is sandwiched between the conveyor belts may be reduced.

Hereinafter, a display device and an electronic device will be described with reference to FIGS. 8 to 10. Each of the display device and the electronic device may include a component (e.g., the display panel DP) to be included in the electronic device disposed in the internal space PNL_H of the tray TR according to the disclosure.

FIG. 8 is a schematic plan view of the display device DD.

Referring to FIG. 8, the display device DD emits light. The display device DD may include the display panel DP which includes a light-emitting element and displays an image (or an image). In an embodiment, the display device DD may display a moving image or a still image. The display device DD may be used as a display screen of various products such as a television, a notebook, a monitor, an advertisement board, and the Internet of things (“IoT”) as well as a portable electronic device such as a mobile phone, a smart phone, a tablet personal computer (“PC”), and a smart watch, a watch phone, a mobile communication terminal, an electronic notebook, an electronic book, a portable multimedia player (“PMP”), navigation, and an Ultra Mobile PC (“UMPC”). However, the application field of the display device DD is not limited to predetermined examples.

The display device DD may have a quadrangular planar shape, e.g., rectangular planar shape having a short side in the first direction DR1 and a long side in the second direction DR2 crossing the first direction DR1. A corner where the short side of the first direction DR1 and the long side of the second direction DR2 meet may be rounded with a predetermined curvature or formed at a right angle. The planar shape of the display device DD is not limited to a rectangle, and may have a shape of another polygon or a round shape such as a circle, or an ellipse. The display device DD may be flat, but the is not limited thereto. In an embodiment, the display device DD is formed at the left and right ends, and may include a curved portion having a constant or varying curvature, for example.

In the disclosure, the first direction DR1 may be a “horizontal” direction in a row direction of a pixel PXL. The second direction DR2 may be a column direction of the pixel PXL. The second direction DR2 may be perpendicular to the first direction DR1. The third direction DR3 may be a display direction of the display device DD or a normal direction of a plane in which a base layer BSL is disposed.

The display device DD may include a display area DA and a non-display area NDA. The non-display area NDA may refer to an area outside the display area DA. The non-display area NDA may surround at least a part of the display area DA.

The display area DA may refer to an area in which the pixel PXL is disposed. The non-display area NDA may refer to an area where the pixel PXL is not disposed. A circuit board PCB including a driving circuit portion connected to the pixel PXL of the display area DA, wirings, and a pad portion on which pads are arranged may be disposed in the non-display area NDA. The circuit board PCB may be connected (or electrically connected) to a part of the display panel DP through a conductive adhesive layer PE disposed on the display panel DP in one region of the display panel DP to generate driving signals to the display panel DP and apply the driving signals to the pixels PXL. In an embodiment, the circuit board PCB may be a flexible circuit board.

The display device DD (or the display panel DP) may have a first area 1A, a second area 2A and a bending area BA. In an embodiment, the first area 1A may include the display area DA and the second area 2A may be the non-display area NDA, for example.

In an embodiment, the second region 2A is disposed on one side of the first region 1A and may be spaced apart from the first region 1A. In an embodiment, the second region 2A may be spaced apart from the first region 1A in a direction opposite to the second direction DR2, for example.

The bending area BA may be disposed between the first area 1A and the second area 2A. The bending area BA may be bent along a bending axis extending in the first direction DR1 crossing the second direction DR2. The bending area BA may be an area in which the display device DD (or the display panel DP) is bent. The display device DD may be flexibly formed to be curled, curved, bent, folded, or rolled.

In an embodiment, the pixel PXL (or subpixels SPX) may include a first subpixel SPX1, a second subpixel SPX2, and a third subpixel SPX3. At least one first subpixel SPX1, at least one second subpixel SPX2, and at least one third subpixel SPX3 may form one pixel unit PXU which emits light of various colors. Although FIG. 8 illustrates that each of the pixels PXL includes three subpixels SPX1, SPX2, and SPX3, that is, the first subpixel SPX1, the second subpixel SPX2 and the third subpixel SPX3, the embodiment of the specification is not limited thereto.

In an embodiment, the pixel PXL (or the subpixels SPX) may be disposed according to a stripe or PENTILE™ arrangement structure or the like. However, the disclosure is not necessarily limited thereto.

The first subpixel SPX1 may emit first light, the second subpixel SPX2 may emit second light, and the third subpixel SPX3 may emit third light. The first light may be light in a red wavelength range, the second light may be light of a green wavelength range, and the third light may be light with a blue wavelength range. The red wavelength range may be approximately 600 nanometers (nm) to 750 nm, the green wavelength range may be approximately 480 nm to 560 nm, and the blue wavelength range may be approximately 370 nm to 460 nm, but the embodiments of the disclosure are not limited thereto.

Each of the first subpixel SPX1, the second subpixel SPX2, and the third subpixel SPX3 may include a light-emitting element which emits light, such as an inorganic light-emitting diode including an inorganic semiconductor or an organic light-emitting diode (“OLED”).

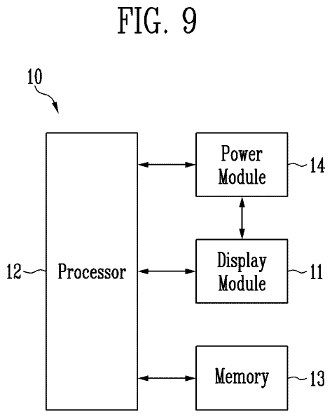

FIG. 9 is a block diagram of an embodiment of an electronic device 10. Referring to FIG. 9, the electronic device 10 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device DD according to the above-described embodiments. In addition, in terms of functionality, some of the individual modules included in one module may be included in the display device DD and others may be provided separately from the display device DD. In an embodiment, the display module 11 is included in the display device, whereas the processor 12, the memory 13, and the power module 14 are not included in the display device DD and are instead provided separately in the electronic device 10, for example.

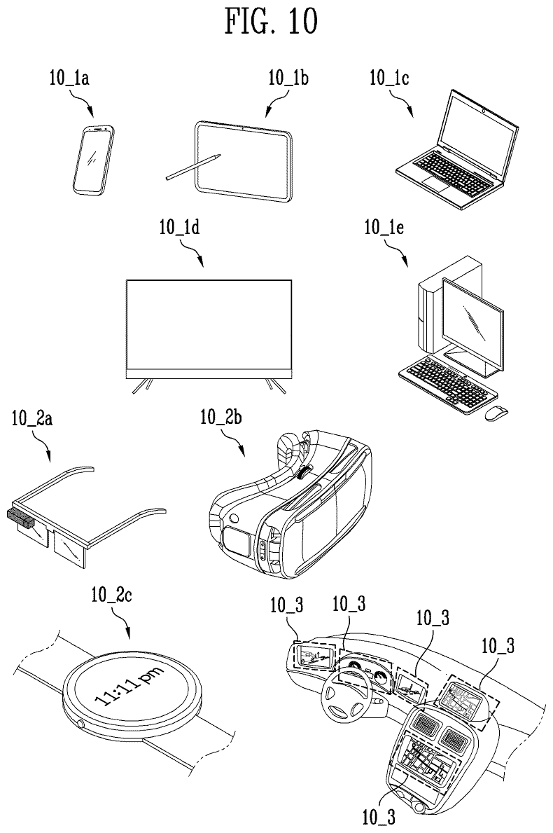

FIG. 10 shows schematic views of various embodiments of an electronic device.

Referring to FIG. 10, various types of electronic devices to which embodiments of the display device DD are applied may include an electronic device to display images such as a smartphone 10_1a, a tablet PC 10_1b, a laptop computer 10_1c, a television (“TV”) 10_1d, and a desktop monitor 10_1e, a wearable electronic device including a display module such as smart glasses 10_2a, a head-mounted display (“HMD”) 10_2b, and a smart watch 10_2c, and an automotive electronic device 10_3 including a display module such as a center information display (“CID”) disposed at the instrument cluster, the center fascia, and the dashboard of a vehicle, and a room mirror display.

By embodiments of the disclosure, a tray capable of reducing a risk that an edge of a display panel is pressed to damage the display panel may be provided.

By embodiments of the disclosure, a tray capable of reducing a risk of occurrence of a phenomenon in which the tray is bent (e.g., tray curl) may be provided.

By embodiments of the disclosure, a tray capable of reducing a risk of fire occurrence may be provided.

The disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A tray comprising:
a first pocket portion in which an internal space accommodating a display panel is defined;
a second pocket portion spaced apart from the first pocket portion in a first direction;
a first air passage disposed at one side of the first pocket portion;
a second air passage disposed between the first pocket portion and the second pocket portion; and
a third air passage disposed at one side of the second pocket portion,
wherein the first air passage and the second air passage are arranged in a first inclined direction inclined with respect to the first direction.

2. The tray of claim 1, wherein the first air passage, the second air passage, and the third air passage are arranged in a zigzag pattern.

3. The tray of claim 1, wherein the third air passage and the second air passage are arranged in a second inclined direction inclined with respect to the first direction.

4. The tray of claim 1, further comprising:
a third pocket portion spaced apart from the second pocket portion in the first direction;
a fourth pocket portion spaced apart from the third pocket portion in the first direction;
a fourth air passage disposed between the third pocket portion and the fourth pocket portion; and
a fifth air passage disposed at one side of the fourth pocket portion.

5. The tray of claim 4, wherein based on a virtual line parallel to the first direction,
the first air passage, the third air passage, and the fifth air passage are arranged at one side with respect to the virtual line, and
the second air passage and the fourth air passage are arranged at an other side with respect to the virtual line.

6. The tray of claim 1, further comprising:
a fifth pocket portion spaced apart from the first pocket portion in a second direction;
a sixth pocket portion spaced apart from the fifth pocket portion in the first direction;
a first stopper disposed at an upper region of the tray in a plan view;
a second stopper disposed in a central region of the tray in the plan view; and
a third stopper disposed in a lower region of the tray in the plan view.

7. The tray of claim 6, wherein the first stopper comprises first stoppers,
the second stopper comprises second stoppers, and
the third stopper comprises third stoppers.

8. The tray of claim 6, wherein each of the first stopper, the second stopper, and the third stopper protrudes further than a lower surface of the tray.

9. The tray of claim 1, wherein the internal space comprises:
a central area disposed at a center of the internal space;
side areas extending from an edge of the central area; and
corner areas extended to the side areas,
wherein the first pocket portion comprises:
a main body portion including an outer wall surrounding at least a part of the side areas; and
a guide portion surrounding the corner areas, and
wherein the guide portion is extended to the outer wall.

10. The tray of claim 9, wherein the main body portion further comprises a circuit board receiving portion, and
wherein the side areas comprise:
a first side area extending from a left side of the central area;
a second side area extending from an upper side of the central area;
a third side area extending from a right side of the central area; and
a fourth side area extending from a lower side of the central area,
wherein the outer wall comprises:
a first outer wall surrounding at least a part of the first side area;
a second outer wall surrounding at least a part of the second side area;
a third outer wall surrounding at least a part of the third side area; and
a fourth outer wall surrounding the circuit board receiving portion, and
wherein the guide portion comprises:
a first guide portion extended to the first outer wall and the second outer wall;
a second guide portion extended to the second outer wall and the third outer wall;
a third guide portion extended to the third outer wall and the fourth outer wall; and
a fourth guide portion extended to the first outer wall and the fourth outer wall.

11. The tray of claim 10, wherein each of the first guide portion, the second guide portion, the third guide portion, and the fourth guide portion has a curved shape in a plan view.

12. The tray of claim 10, wherein the corner areas comprise:
a first corner area disposed at an upper left of the internal space;
a second corner area disposed at an upper right of the internal space;
a third corner area disposed at a lower right of the internal space; and
a fourth corner area disposed at a lower left of the internal space, and
wherein the first corner area is connected to the first guide portion, and
the second corner area is connected to the second guide portion,
the third corner area is connected to the third guide portion, and
the fourth corner area is connected to the fourth guide portion.

13. A tray comprising:
a first pocket portion in which an internal space accommodating a display panel is defined, the first pocket portion comprising:
a main body portion including an outer wall; and
a guide portion extended to the outer wall,
wherein the internal space comprises:
a central area disposed at a center of the internal space;
side areas extending from edges of the central area; and
corner areas connecting the side areas, and
the outer wall surrounds at least a part of the side areas, and
the guide portion surrounds the corner areas.

14. The tray of claim 13, further comprising:
a second pocket portion spaced apart from the first pocket portion in a first direction;
a first air passage disposed at one side of the first pocket portion;
a second air passage disposed between the first pocket portion and the second pocket portion; and
a third air passage disposed at one side of the second pocket portion,
wherein the first air passage and the second air passage are arranged in a first inclined direction inclined with respect to the first direction.

15. The tray of claim 14, wherein based on a virtual line parallel to the first direction,
the first air passage and the third air passage are arranged on one side with respect to the virtual line, and
the second air passage is disposed at an other side with respect to the virtual line.

16. The tray of claim 14, wherein the third air passage and the second air passage are arranged in a second inclined direction inclined with respect to the first direction.

17. The tray of claim 13, further comprising:
a fifth pocket portion spaced apart from the first pocket portion in a second direction;
a sixth pocket portion spaced apart from the fifth pocket portion in a first direction;
a first stopper disposed in an upper region of the tray in a plan view;
a second stopper disposed in a central region of the tray in the plan view; and
a third stopper disposed in a lower region of the tray in the plan view.

18. The tray of claim 17, wherein the first stopper comprises first stoppers,
the second stopper comprises second stoppers,
the third stopper comprises third stoppers, and
each of the first stopper, the second stopper, and the third stopper protrudes further than a lower surface of the tray.

19. The tray of claim 13, wherein the main body portion further comprises a circuit board receiving portion,
wherein the side areas comprise:
a first side area extending from a left side of the central area;
a second side area extending from an upper side of the central area;
a third side area extending from a right side of the central area; and
a fourth side area extending from a lower side of the central area,
wherein the outer wall comprises:
a first outer wall surrounding at least a part of the first side area;
a second outer wall surrounding at least a part of the second side area;
a third outer wall surrounding at least a part of the third side area; and
a fourth outer wall surrounding the circuit board receiving portion, and
wherein the guide portion comprises:
a first guide portion extended to the first outer wall and the second outer wall;
a second guide portion extended to the second outer wall and the third outer wall;
a third guide portion extended to the third outer wall and the fourth outer wall; and
a fourth guide portion extended to the first outer wall and the fourth outer wall, and
wherein each of the first guide portion, the second guide portion, the third guide portion, and the fourth guide portion has a curved shape in a plan view.

20. The tray of claim 19, wherein the corner areas comprise:
a first corner area disposed at an upper left of the internal space;
a second corner area disposed at an upper right of the internal space;
a third corner area disposed at a lower right of the internal space; and
a fourth corner area disposed at a lower left of the internal space, and
wherein the first corner area is connected to the first guide portion,
the second corner area is connected to the second guide portion,
the third corner area is connected to the third guide portion, and
the fourth corner area is connected to the fourth guide portion.
